(19) United States
(12) Patent Application Publication
(10) Pub. No.: US 2025/0270867 A1
(43) Pub. Date: Aug. 28, 2025

(54) VEHICLE DOOR PINCH DETECTION DEVICE WITH IMPROVED DETECTION PERFORMANCE

(71) Applicants: Hyundai Motor Company, Seoul (KR); Kia Corporation, Seoul (KR); Damoatech Co.,Ltd, Seongnam-si (KR); AUTOMOBILE INDUSTRIAL ACE, Ansan-si (KR); WINNERCOM Co.,LTD, Gimhae-si (KR)

(72) Inventors: Hyung-Sik CHOI, Hwaseong-si (KR); Jae-Seung LEE, Hwaseong-si (KR); Ho-Dong KIM, Hwaseong-si (KR); Sang-Hyun LEE, Hwaseong-si (KR); Hak-Hui CHOI, Bucheon-Si (KR); Eui-Suk JEONG, Bucheon-Si (KR); Jun-Young SHIN, Suwon-Si (KR); Hu-Min JUNG, Hanam-Si (KR)

(73) Assignees: Hyundai Motor Company, Seoul (KR); Kia Corporation, Seoul (KR); Damoatech Co.,Ltd, Seongnam-si (KR); AUTOMOBILE INDUSTRIAL ACE, Ansan-si (KR); WINNERCOM Co.,LTD., Gimhae-si (KR)

(21) Appl. No.: 18/958,710

(22) Filed: Nov. 25, 2024

(30) Foreign Application Priority Data
Feb. 28, 2024 (KR) 10-2024-0029172

(51) Int. Cl. E05F 15/44; B60J 5/04; B60J 10/86

(52) U.S. Cl. CPC E05F 15/44; B60J 5/0479; B60J 10/86; E05Y 2900/531

(57) ABSTRACT

A vehicle door pinch detection apparatus with improved detection performance includes a door provided on one side of a vehicle, an external pinch sensor configured for detecting a pinch on an external side of the door at a position where an end portion of the door abuts against a body of the vehicle or another door of the vehicle upon closing of the door, and an internal pinch sensor configured for detecting a pinch on an internal side of the door at a position where the end portion of the door abuts against the body or another door of the vehicle upon closing of the door.

### CROSS-REFERENCE TO RELATED APPLICATION

The present application claims priority to Korean Patent Application No. 10-2024-0029172, filed on Feb. 28, 2024, the entire contents of which is incorporated herein for all purposes by this reference.

### BACKGROUND OF THE PRESENT DISCLOSURE

### Field of the Present Disclosure

The present disclosure relates to a vehicle door pinch detection apparatus adapted to a vehicle door to detect pinching of an occupant's body while closing of the vehicle door and more particularly, to a vehicle door pinch detection apparatus configured for detecting door pinch situations from an inside and an outside of a vehicle to improve detection performance.

### Description of Related Art

Anti-pinch sensors are provided on a vehicle door to detect a pinch of an occupant's body or belongings between a vehicle door being closed and a vehicle body, or between the vehicle doors when the occupant gets in or out of the vehicle.

The anti-pinch sensors are typically provided inside a weather strip provided around a periphery of the vehicle door, so that in the event of the pinch, the weather strip is first deformed and then the anti-pinch sensors detect a deformation of the weather strip and therefore an occurrence of the pinch.

Purpose-built vehicles (PBVs) that operate based on autonomous driving are expected to be utilized as passenger transportation vehicles. As the PBVs are operated without a driver, there is a need to increase a reliability of the in-vehicle safety systems.

For example, a pinch occurring upon the door closing needs to be detected very precisely in the absence of the driver to avoid unnecessary malfunctions and safety accidents.

The information included in this Background of the present disclosure is only for enhancement of understanding of the general background of the present disclosure and may not be taken as an acknowledgement or any form of suggestion that this information forms the prior art already known to a person skilled in the art.

### BRIEF SUMMARY

Various aspects of the present disclosure are directed to providing a vehicle door pinch detection apparatus configured for detecting door pinch situations from an inside and an outside of a vehicle to improve detection performance.

Various aspects of the present disclosure are directed to providing a vehicle door pinch detection apparatus with improved detection performance, the device including: a door provided on one side of a vehicle; an external pinch sensor configured for detecting a pinch on an external side of the door at a position where an end portion of the door abuts against a body of the vehicle or another door of the vehicle upon closing of the door; and an internal pinch sensor configured for detecting a pinch on an internal side of the door at a position where the end portion of the door abuts against the body of the vehicle or another door of the vehicle upon closing of the door.

The external pinch sensor may be provided in an external weather strip provided on an external side of the door, and the internal pinch sensor may be provided in an internal weather strip provided on an internal side of the door.

The external weather strip may include: a first fixing portion fixedly fitted to the door, a first insert inserted into the first fixing portion; a first sealing portion formed on an external side of the first fixing portion to abut against the body of the vehicle or another door of the vehicle; and a first sensor portion formed to be connected to the first sealing portion from the external side of the first fixing portion, wherein the external pinch sensor is provided in an interior of the first sensor portion.

The external pinch sensor may be a contact sensor configured for detecting a pinch with a variable resistance and including a plurality of members spaced apart from each other.

The external pinch sensor may include a first member mounted on one side of the interior of the first sensor portion, and a second member mounted spaced apart from the first member on the other side of the interior of the first sensor portion.

The external weather strip may be made of a non-conductive rubber, and the first member and the second member may be made of a conductive rubber.

The first member and the second member may be configured to be electrically connected to each other when the external weather strip is deformed due to the pinch.

One of the first member and the second member may be formed in the shape of a concave groove, and the other of the first member and the second member may be formed in the shape of a protrusion to be accommodated in the concave groove.

The external weather strip may include a bridge portion formed between the first sealing portion and the first sensor portion to separate the first sealing portion and the first sensor portion.

The internal weather strip may include: a second fixing portion fixedly fitted to the door, a second insert inserted into the second fixing portion; a second sealing portion formed on an external side of the second fixing portion to abut against the body of the vehicle or the other door of the vehicle; and a second sensor portion formed to protrude from the second fixing portion at a position spaced apart from the second sealing portion, wherein the internal pinch sensor is provided on the interior of the second sensor portion.

The internal pinch sensor may be a non-contact sensor configured for detecting a pinch with a change in impedance when the occupant's body touches the second sensor portion.

Two or more internal pinch sensors may be provided to be spaced apart from each other in the second sensor portion in a direction in which the second sensor portion protrudes.

The second sensor portion may be made of a non-conductive rubber.

The door may include sliding-type front and rear door sections slidably provided on the vehicle in a longitudinal direction of the vehicle, wherein the external weather strip and the internal weather strip are provided on a front end portion of the rear door section in a height direction of the vehicle, and when the front door section and the rear door section are closed, the external weather strip and the internal weather strip abut against a rear end portion of the front door section.

The first sealing portion may be formed in a hollow shape on the external side of the first fixing portion.

The first sensor portion may be formed in a hollow shape to accommodate the external pinch sensor therein.

The second sealing portion may be formed in a hollow shape on the external side of the second fixing portion.

The second sensor portion may be formed to surround a portion of an external side of a door trim of the door on which the internal weather strip is provided.

The first insert may be previously inserted into the interior of the first fixing portion to ensure the first fixing portion to be fitted around the door panel.

The second fixing portion may be configured to be molded with the second insert at the time of molding.

According to the vehicle door pinch detection apparatus including the above-mentioned configurations with improved detection performance, a pinch may be detected on the internal and external sides of the vehicle when the door is closed, improving a precision of pinch detection.

Furthermore, since the pinch may be detected on the external side of the vehicle in a resistance-detective manner, it is possible to easily detect a pinch due to an object as well as a passenger's body, and thus prevent pinching accidents on the external side of the door.

Furthermore, since the door pinch by the occupant's body may be detected on an internal side of the vehicle in an impedance-detective manner, it is possible to detect the pinch by the occupant's body when the door is closing, while the occupant seats in the vehicle.

Since the pinch by the occupant's body or the object may be detected in different ways on the outside and the interior of the vehicle, it is possible to prevent a safety accident caused by the occupant's body being directly pinched in the door, or a safety accident caused by the occupant's belongings being pinched in the door and dragged.

The methods and apparatuses of the present disclosure have other features and advantages which will be apparent from or are set forth in more detail in the accompanying drawings, which are incorporated herein, and the following Detailed Description, which together serve to explain certain principles of the present disclosure.

### BRIEF DESCRIPTION OF THE DRAWINGS

FIG. 1 is a side diagram illustrating a vehicle including a vehicle door pinch detection apparatus with improved detection performance according to an exemplary embodiment of the present disclosure;

FIG. 2 is a cross-sectional diagram taken along line I-I of FIG. 1;

FIG. 3 is a perspective diagram seen from an outside of the vehicle in which an external weather strip and an internal weather strip are provided at a rear door section with an external pinch sensor and an internal pinch sensor of the vehicle door pinch detection apparatus according to an exemplary embodiment of the present disclosure provided thereon;

FIG. 4 is a perspective diagram seen from the interior of the vehicle in which an external weather strip and an internal weather strip are provided at the rear door section with an external pinch sensor and an internal pinch sensor of the vehicle door pinch detection apparatus according to an exemplary embodiment of the present disclosure provided thereon;

FIG. 5 is a cross-sectional diagram illustrating a state in which an external pinch sensor of the vehicle door pinch detection apparatus according to an exemplary embodiment of the present disclosure is provided on the external weather strip;

FIG. 6 is a cross-sectional diagram illustrating a state of the external pinch sensor of FIG. 5 detecting the door pinch situation;

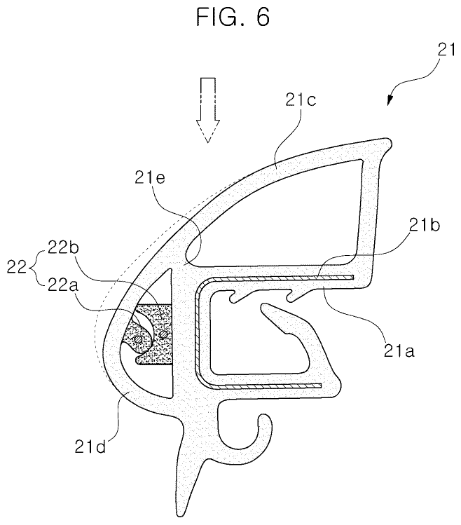

FIG. 7 is a cross-sectional diagram illustrating a state in which an external pinch sensor of the vehicle door pinch detection apparatus according to another exemplary embodiment of the present disclosure is provided on the external weather strip;

FIG. 8 is a cross-sectional diagram illustrating a state in which an internal pinch sensor of the vehicle door pinch detection apparatus according to an exemplary embodiment of the present disclosure is provided on the internal weather strip; and

FIG. 9 is a cross-sectional diagram illustrating a state in which an internal pinch sensor of the vehicle door pinch detection apparatus according to another exemplary embodiment of the present disclosure is provided on the internal weather strip.

It may be understood that the appended drawings are not necessarily to scale, presenting a somewhat simplified representation of various features illustrative of the basic principles of the present disclosure. The specific design features of the present disclosure as included herein, including, for example, specific dimensions, orientations, locations, and shapes locations, and shapes will be determined in part by the particularly intended application and use environment.

In the figures, reference numbers refer to the same or equivalent portions of the present disclosure throughout the several figures of the drawing.

### DETAILED DESCRIPTION

Reference will now be made in detail to various embodiments of the present disclosure(s), examples of which are illustrated in the accompanying drawings and described below. While the present disclosure(s) will be described in conjunction with exemplary embodiments of the present disclosure, it will be understood that the present description is not intended to limit the present disclosure(s) to those exemplary embodiments of the present disclosure. On the other hand, the present disclosure(s) is/are intended to cover not only the exemplary embodiments of the present disclosure, but also various alternatives, modifications, equivalents and other embodiments, which may be included within the spirit and scope of the present disclosure as defined by the appended claims.

Hereinafter, a vehicle door pinch detection apparatus with improved detection performance according to an exemplary embodiment of the present disclosure will be described in detail with reference to the accompanying drawings.

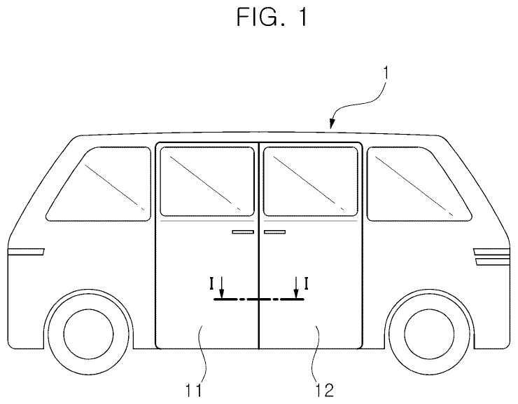

FIG. 1 illustrates an example of a vehicle 1 including a vehicle door pinch detection apparatus with improved detection performance according to an exemplary embodiment of the present disclosure. The vehicle door pinch detection apparatus according to an exemplary embodiment of the present disclosure may be preferably applied to a vehicle 1 in which a pair of door sections 11 and 12 are slidably provided. The present disclosure may be applied to the vehicle 1, such as a purpose-built vehicle (PBV) between a front door section 11 and a rear door section 12.

In the vehicle 1 illustrated in FIG. 1, the front door section 11 may slidably open toward the front of the vehicle 1 and the rear door section 12 may slidably open toward the rear of the vehicle 1, wherein the vehicle door pinch detection apparatus of the present disclosure is provided to detect a pinch between the front door section 11 and the rear door section 12. of course, the vehicle door pinch detection system may also be applied to a vehicle in which the door sections are opened or closed in a swinging manner to detect a pinch between the vehicle door section and a vehicle body.

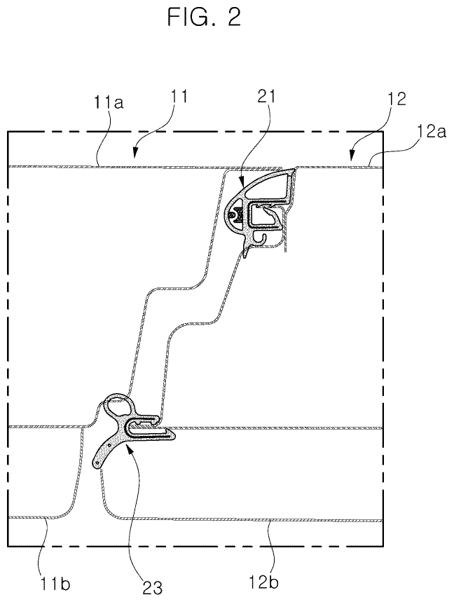

FIG. 2 illustrates a cross section at a position where the vehicle door pinch detection apparatus of the present disclosure is provided. An external pinch sensor 22 and an internal pinch sensor 24 for detecting a pinch between the front door section 11 and the rear door section 12 may be provided on an external weather strip 21 and an internal weather strip 23, respectively.

When the front door section 11 and the rear door section 12 are closed, the external pinch sensor 22 may detect a pinch on the external side of the door 11 and 12, and the internal pinch sensor 24 may detect a pinch on the internal side of the door 11 and 12.

The front door section 11 and the rear door section 12 may include door panels 11a and 12a, respectively, with door trims 11b and 12b on the internal side of the vehicle 1.

The external weather strip 21 and the internal weather strip 23 may be provided on any one of the front door sections 11 or the rear door section 12 to provide a sealing between the front door section 11 and the rear door section 12 when the front door section 11 and the rear door section 12 are closed.

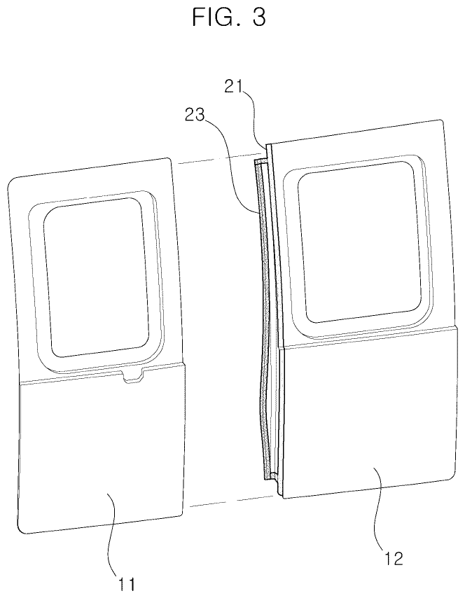

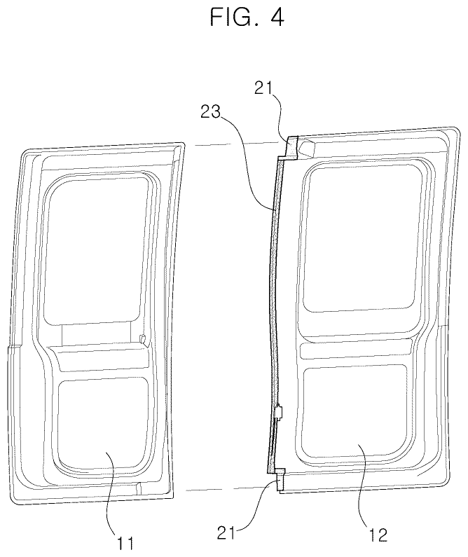

For example, as illustrated in FIG. 3 and FIG. 4, the external weather strip 21 and the internal weather strip 23 may be provided on the front end portion of the rear door section 12 so that the external weather strip 21 is fitted on the external side of the front end portion of the rear door section 12 and the internal weather strip 23 is fitted on the internal side of the front end portion of the rear door section 12. Thus, the external weather strip 21 and the internal weather strip 23 may seal the exterior and internal sides, respectively, of the vehicle 1 between the rear end portion of the front door section 11 and the front end portion of the rear door section 12.

The external pinch sensor 22 may be integrally formed with the other weather strip 21 on the external weather strip 21.

The external weather strip 21 may include a first fixing portion 21a fixedly fitted to one side of the door 11 or 12, a first insert 21b inserted into an interior of the first fixing portion 21a, a first hollow sealing portion 21c formed on an external side of the first fixing portion 21a to abut against the body or the other door 12 or 11 of the vehicle 1, and a first hollow sensor portion 21d formed to be connected to the first sealing portion 21c from the external side of the first fixing portion 21a.

The first insert 21b may be fabricated in a state of being previously inserted into the interior of the first fixing portion 21a, which is fixedly fitted on the door 11 or 12, for example, around the door panel 12a of the rear door section 12. The first insert 21b may ensure that the first fixing portion 21a remains fitted around the door panel 11a or 12a.

The first sealing portion 21c may be convexly formed in a hollow shape on the external side of the first fixing portion 21a to seal the door 11 or 12 against the other door 12 or 11 or the vehicle body side when the door 11 or 12 is closed.

The first sensor portion 21d may also be formed on the external side of the first fixing portion 21a. The external surface of the first sensor portion 21d may be formed to connect with the external surface of the first sealing portion 21c. The line connecting the external surface of the first sealing portion 21c and the external surface of the first sensor portion 21d may be formed in a form of a single curve, which becomes an exposed portion to the outside when the door 11 or 12 is opened.

The external pinch sensor 22 may be provided on the internal side of the first sensor portion 21d. The external pinch sensor 22 may be a contact sensor which is configured to detect a pinch by a variable resistance occurring when two spaced apart members 22a and 22b are brought into contact.

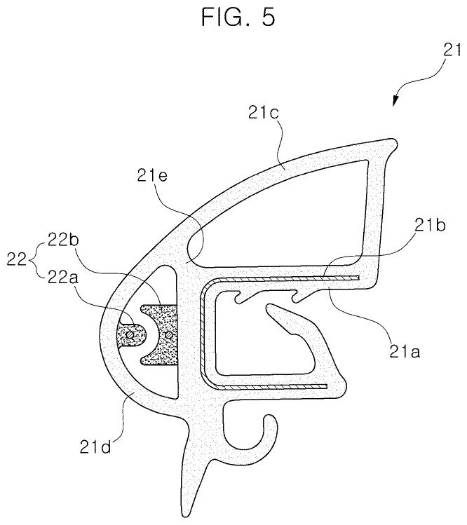

The first member 22a and the second member 22b forming the external pinch sensor 22 may be provided spaced apart from each other on the internal surface of the first sensor portion 21d. For example, the first member 22a and the second member 22b may be provided opposite to each other on the internal surface of the first sensor portion 21d. That is, as illustrated in FIG. 5, the first member 22a may be provided on one side of the internal surface of the first sensor portion 21d, and the second member 22b may be provided on the other side of the internal surface of the first sensor portion 21d so that the first member 22a and the second member 22b are opposite to each other. Since the first member 22a and the second member 22b are made of a conductive rubber material, the first member 22a and the second member 22b may not be electrically connected to each other in a normal state in which the first member 22a and the second member 22b are spaced apart from each other. However, when the first and second members 22a and 22b become into contact with each other due to a pinch, the pinch is detected through a difference in voltage generated by a change in resistance in a circuit connected to the external pinch sensor 22. The circuit for detecting the pinch through the external pinch sensor 22 may include two resistors connected in parallel, wherein one of the resistors is connected in series with the external pinch sensor 22. In the instant case, normally current flows only through one resistor, but when a pinch occurs, current flows through both resistors, causing the resistance of the entire circuit to change, resulting in a voltage difference, which indicates the occurrence of the pinch.

The first member 22a may be formed in the shape of a protrusion, and the second member 22b may be formed in the shape of a concave groove in which an end portion of the first member 22a is accommodated. As the end portion of the first member 22a is formed to be surrounded by the second member 22b, the end portion of the first member 22a may be brought into contact with the second member 22b when a pinch occurs.

Since a circumferential portion of the first sensor portion 21d other than an area where the first sensor portion 21d supports the first member 22a and the second member 22b provided thereon are more deformable than such the area, when the external surface of the external weather strip 21 is deformed due to the pinch, the first member 22a and the second member 22b may be easily contact with each other, which facilitates quick detection of the pinch.

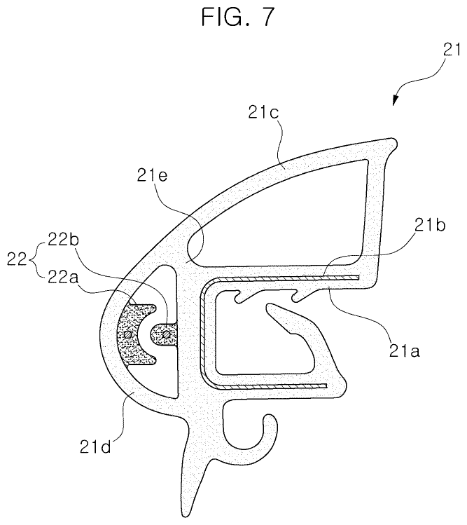

Alternatively, as illustrated in FIG. 7, the second member 22b may be formed in the shape of a protrusion, and the first member 22a may be formed in the shape of a concave groove in which an end portion of the second member 22b is accommodated.

The external weather strip 21 may be made of a non-conductive rubber material. Since the external weather strip 21 is made of a non-conductive material, the first member 22a and second member 22b may not be electrically connected in a normal state. Furthermore, since the external weather strip 21 is made of rubber, when the front door section 11 and the rear door section 12 are closed, the first sealing portion 21c may deform to seal the rear end portions of the front door section 11 and the front end portion of the rear door section 12, and prevent injury to the occupant's body in the event of pinching.

The external weather strip 21 may include a bridge portion 21e formed between the first sealing portion 21c and the first sensor portion 21d to separate the first sealing portion 21c and the first sensor portion 21d. The bridge portion 21e may separate the first sealing portion 21c and the first sensor portion 21d, while preventing external lines of the first sealing portion 21c and the first sensor portion 21d from being separated from the first fixing portion 21a. Accordingly, each of the internal space of the first sealing portion 21c and the first sensor portion 21d may be formed into a closed cross-section of a certain size, so that the sealing performance of the first sealing portion 21c is improved, and installation positions of the first member 22a and the second member 22b are maintained in the first sensor portion 21d.

The internal pinch sensor 24 may be integrally formed with the internal weather strip 23 on the internal weather strip 23.

The internal weather strip 23 may include a second fixing portion 23a fixedly fitted to the door 11 or 12, a second insert 23b inserted into an interior of the second fixing portion 23a, a second hollow sealing portion 23c formed on an external side of the second fixing portion 23a to abut against the body or the other door 12 or 11 of the vehicle 1, and a second sensor portion 23d formed to protrude from the second fixing portion 23a at a distance from the second sealing portion 23c.

The second fixing portion 23a may be fixed to the internal weathers trip 23 by fitting around the door panel 11a or 12a forming the door 11 or 12. The second fixing portion 23a may be molded with the second insert 23b inserted therein at the time of molding, so that the second fixing portion 23a remains inserted in the door panel 11a or 12a.

The second sealing portion 23c may be convexly formed in a hollow shape on one side of the second fixing portion 23a. The second sealing portion 23c may be pressed against the other door 12 or 11 or the vehicle body.

The second sensor portion 23d may be formed to protrude from the second fixing portion 23a at a distance from the second sealing portion 23c. The second sensor portion 23d may be formed to protrude from the second fixing portion 23a and surround a portion of an external side of a door trim 11b or 12b of the door 11 or 12 on which the internal weather strip 23 is provided. For example, when the internal weather strip 23 is provided on the rear door 12, the second sensor portion 23d may be formed to surround a portion of the door trim 12b of the rear door section 12.

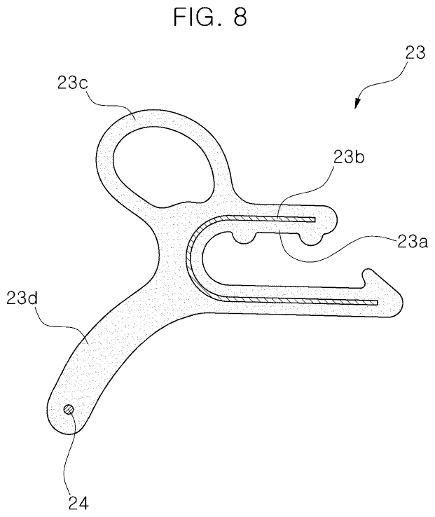

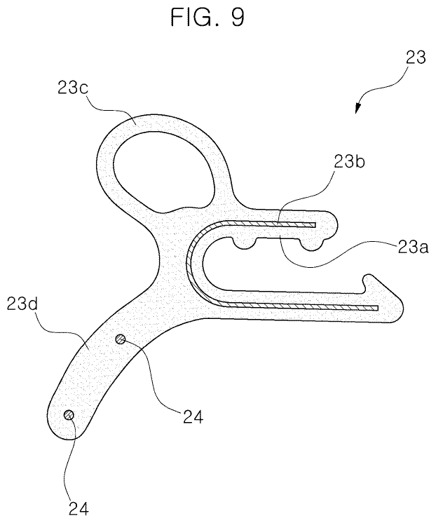

At least one internal pinch sensor 24 may be provided on the second sensor portion 23d. The internal pinch sensor 24 may be provided as an impedance-detective type sensor that generally detects an object, e.g., a user's touch on a flat screen or the like. The internal pinch sensor 24 may detect a pinch with a change in the impedance value when the occupant's body touches the second sensor portion 23d. When the impedance-detective type sensor is applied as the internal pinch sensor 24, the impedance-detective type sensor may have a high frequency band so that the output value varies depending on the object in contact with the sensor, allowing the pinch of the occupant's body to be detected accurately. If the second sensor portion 23d comes into contact with moisture, the second sensor portion 23d may transmit an output that differs from the pinching of the occupant's body. At least one internal pinch sensor 24 may be provided on the second sensor portion 23d. That is, as illustrated in FIG. 8, only one internal pinch sensor 24 may be provided, or as illustrated in FIG. 9, two or more internal pinch sensors 24 may be provided spaced apart from each other. If two or more internal pinch sensors 24 are provided, respective internal pinch sensors 24 may be used for different purposes. For example, if two internal pinch sensors 24 are provided, one internal pinch sensor 24 may detect an occupant's body touch and the other internal pinch sensor 24 may detect moisture, adjusting a sensitivity of the internal pinch sensors 24 to the occupant's body touch in rainy weather.

The whole portion of the internal weather strip 23 or only a portion of the internal weather strip 23 where the internal pinch sensor 24 is provided may be made of a non-conductive rubber material so as not to affect an operation of the internal pinch sensor 24.

As another exemplary embodiment of the present disclosure, the internal pinch sensor 24 may be a capacitive type sensor which is configured to detect a touch with a change in capacitance, instead of an impedance-detective type sensor.

In an exemplary embodiment of the present disclosure, the vehicle may be referred to as being based on a concept including various means of transportation. In some cases, the vehicle may be interpreted as being based on a concept including not only various means of land transportation, such as cars, motorcycles, trucks, and buses, that drive on roads but also various means of transportation such as airplanes, drones, ships, etc.

For convenience in explanation and accurate definition in the appended claims, the terms “upper”, “lower”, “inner”, “outer”, “up”, “down”, “upwards”, “downwards”, “front”, “rear”, “back”, “inside”, “outside”, “inwardly”, “outwardly”, “interior”, “exterior”, “internal”, “external”, “forwards”, and “backwards” are used to describe features of the exemplary embodiments with reference to the positions of such features as displayed in the figures. It will be further understood that the term “connect” or its derivatives refer both to direct and indirect connection.

The term “and/or” may include a combination of a plurality of related listed items or any of a plurality of related listed items. For example, “A and/or B” includes all three cases such as “A”, “B”, and “A and B”.

In exemplary embodiments of the present disclosure, “at least one of A and B” may refer to “at least one of A or B” or “at least one of combinations of at least one of A and B”. Furthermore, “one or more of A and B” may refer to “one or more of A or B” or “one or more of combinations of one or more of A and B”.

In the present specification, unless stated otherwise, a singular expression includes a plural expression unless the context clearly indicates otherwise.

In the exemplary embodiment of the present disclosure, it should be understood that a term such as “include” or “have” is directed to designate that the features, numbers, steps, operations, elements, parts, or combinations thereof described in the specification are present, and does not preclude the possibility of addition or presence of one or more other features, numbers, steps, operations, elements, parts, or combinations thereof.

According to an exemplary embodiment of the present disclosure, components may be combined with each other to be implemented as one, or some components may be omitted.

The foregoing descriptions of specific exemplary embodiments of the present disclosure have been presented for purposes of illustration and description. They are not intended to be exhaustive or to limit the present disclosure to the precise forms disclosed, and obviously many modifications and variations are possible in light of the above teachings. The exemplary embodiments were chosen and described in order to explain certain principles of the invention and their practical application, to enable others skilled in the art to make and utilize various exemplary embodiments of the present disclosure, as well as various alternatives and modifications thereof. It is intended that the scope of the present disclosure be defined by the Claims appended hereto and their equivalents.

What is claimed is:

1. A vehicle door pinch detection apparatus with improved detection performance, the apparatus comprising:
a door provided on one side of a vehicle;
an external pinch sensor configured for detecting a pinch on an external side of the door at a position where an end portion of the door abuts against a body of the vehicle or another door of the vehicle upon closing of the door; and
an internal pinch sensor configured for detecting a pinch on an internal side of the door at a position where the end portion of the door abuts against the body of the vehicle or another door of the vehicle upon closing of the door.

2. The vehicle door pinch detection apparatus of claim 1, wherein the external pinch sensor is provided in an external weather strip provided on the external side of the door, and the internal pinch sensor is provided in an internal weather strip provided on the internal side of the door.

3. The vehicle door pinch detection apparatus of claim 2, wherein the external weather strip includes:
a first fixing portion fixedly fitted to the door;
a first insert inserted into the first fixing portion;
a first sealing portion formed on an external side of the first fixing portion to abut against the body of the vehicle or another door of the vehicle; and
a first sensor portion formed to be connected to the first sealing portion from the external side of the first fixing portion, wherein the external pinch sensor is provided in an interior of the first sensor portion.

4. The vehicle door pinch detection apparatus of claim 3, wherein the external pinch sensor is a contact sensor configured for detecting the pinch with a variable resistance and includes a plurality of members spaced apart from each other.

5. The vehicle door pinch detection apparatus of claim 4, wherein the plurality of members of the external pinch sensor includes:
a first member mounted on a first side of the interior of the first sensor portion; and
a second member mounted spaced apart from the first member on a second side of the interior of the first sensor portion.

6. The vehicle door pinch detection apparatus of claim 5, wherein the external weather strip is made of a non-conductive rubber, and the first member and the second member are made of a conductive rubber.

7. The vehicle door pinch detection apparatus of claim 5, wherein the first member and the second member are configured to be electrically connected to each other in response that the external weather strip is deformed due to the pinch.

8. The vehicle door pinch detection apparatus of claim 5, wherein one of the first member and the second member is formed in a shape of a concave groove, and the other of the first member and the second member is formed in a shape of a protrusion to be accommodated in the concave groove.

9. The vehicle door pinch detection apparatus of claim 3, wherein the external weather strip includes a bridge portion formed between the first sealing portion and the first sensor portion to separate the first sealing portion and the first sensor portion.

10. The vehicle door pinch detection apparatus of claim 2, wherein the internal weather strip includes:
a second fixing portion fixedly fitted to the door;
a second insert inserted into the second fixing portion;
a second sealing portion formed on the external side of the second fixing portion to abut against the body of the vehicle or another door of the vehicle; and
a second sensor portion formed to protrude from the second fixing portion at a position spaced apart from the second sealing portion, wherein the internal pinch sensor is provided on an interior of the second sensor portion.

11. The vehicle door pinch detection apparatus of claim 10, wherein the internal pinch sensor is a non-contact sensor configured for detecting the pinch with a change in impedance in response that an occupant's body touches the second sensor portion.

12. The vehicle door pinch detection apparatus of claim 10, wherein the internal pinch sensor is in plural and the plurality of internal pinch sensors are provided to be spaced apart from each other in the second sensor portion in a direction in which the second sensor portion protrudes.

13. The vehicle door pinch detection apparatus of claim 11, wherein the second sensor portion is made of a non-conductive rubber.

14. The vehicle door pinch detection apparatus of claim 2,
wherein the door includes sliding-type front and rear door sections slidably provided on the vehicle in a longitudinal direction of the vehicle, and
wherein the external weather strip and the internal weather strip are provided on a front end portion of the rear door section in a height direction of the vehicle, and in response that the front door section and the rear door section are closed, the external weather strip and the internal weather strip abut against a rear end portion of the front door section.

15. The vehicle door pinch detection apparatus of claim 3, wherein the first sealing portion is formed hollow on the external side of the first fixing portion.

16. The vehicle door pinch detection apparatus of claim 15, wherein the first sensor portion is formed hollow to accommodate the external pinch sensor therein.

17. The vehicle door pinch detection apparatus of claim 10, wherein the second sealing portion is formed hollow on the external side of the second fixing portion.

18. The vehicle door pinch detection apparatus of claim 17, wherein the second sensor portion is formed to surround a portion of the external side of a door trim of the door on which the internal weather strip is provided.

19. The vehicle door pinch detection apparatus of claim 3, wherein the first insert is previously inserted into an interior of the first fixing portion to ensure the first fixing portion to be fitted around a door panel.

20. The vehicle door pinch detection apparatus of claim 10, wherein the second fixing portion is configured to be molded with the second insert.
